(19) United States
(12) Patent Application Publication
(10) Pub. No.: US 2010/0263916 A1
(43) Pub. Date: Oct. 21, 2010

(54) Circuit board assembly

(75) Inventor: Chien-Chung Lee, Taichung Hsien (TW)

Correspondence Address: TESSARI PATENT LAW GROUP, PLLC, 301 LINDENWOOD DRIVE - SUITE 206, MALVERN, PA, 19355, US

(73) Assignee: Sunrex Technology Corporation, Taichung Hsien (TW)

(21) Appl. No.: 12/460,934

(22) Filed: Jul. 27, 2009

(30) Foreign Application Priority Data
Apr. 21, 2009 (TW) 098113165

(51) Int. Cl. H05K 1/00

(52) U.S. Cl. 174/254

(57) ABSTRACT

A circuit board assembly includes a printed circuit board having a board substrate, a transmission member having a flexible substrate, and an elastic clamping frame. The elastic clamping frame is in the form of a single piece and includes upper and lower walls and press protrusions protruding from one of the upper and lower walls. A stack of a connecting portion of the flexible substrate and a connecting portion of the board substrate is tightly disposed between the upper and lower walls such that each of the conductive fingers of the transmission member and a corresponding one of the conductive fingers of the printed circuit board are pressed against each other by the pressing action of the press protrusions.

### BACKGROUND OF THE INVENTION

1. Field of the Invention

This invention relates to a circuit board assembly including a printed circuit board and a transmission member connected to the printed circuit board.

2. Description of the Related Art

Typically, in an electronic device such as a keyboard, a flexible printed circuit (FPC) is attached to a printed circuit board (PCB) such that conductive fingers of the FPC are electrically connected to conductive fingers of the PCB respectively.

FIGS. 1 and 2 illustrate a conventional PCB assembly including a PCB 1 and an FPC 2 attached to the PCB 1 through a fastening device. The fastening device includes a rigid iron plate 4, an elastic plate 5, a plurality of screws 6, and a plurality of threaded posts 31 provided on a keyboard casing 3. The rigid iron plate 4, the elastic plate 5, the FPC 2, and the PCB 1 are stacked sequentially above the casing 3 to form a stack and are secured to the casing 3 by extending the screws 6 through the stack and fastening the screws 6 to the threaded posts 31, respectively. The PCB 1 has a plurality of conductive fingers 101. The FPC 2 has a plurality of conductive fingers 201, each of which is stacked on a corresponding one of the conductive fingers 101 of the PCB 1. The elastic plate 5 has a plurality of press protrusions 501 extending downwardly in a direction toward the conductive fingers 101, 201 and elastically pressing the FPC 2 against the PCB 1 as a result of the fastening of the screws 6. The conventional PCB assembly is disadvantageous in that it is time consuming to assemble the PCB assembly through the screws 6. Furthermore, the screws 6 and the rigid iron plate 4 significantly increase the weight of the PCB assembly.

### SUMMARY OF THE INVENTION

Therefore, the object of the present invention is to provide a circuit board assembly that can overcome the aforesaid drawbacks associated with the prior art.

According to this invention, there is provided a circuit board assembly that comprises a printed circuit board, a transmission member, and an elastic clamping frame. The printed circuit board includes a board substrate and a plurality of spaced apart conductive fingers. The board substrate has a connecting portion. The conductive fingers are disposed on the connecting portion of the board substrate. The transmission member includes a flexible substrate and a plurality of spaced apart conductive fingers. The flexible substrate has a connecting portion. The conductive fingers are disposed on the connecting portion of the flexible substrate. The connecting portion of the flexible substrate and the connecting portion of the board substrate are stacked one above the other to form a stack such that each of the conductive fingers of the transmission member is stacked on a corresponding one of the conductive fingers of the printed circuit board. The elastic clamping frame is in the form of a single piece and includes upper and lower walls. At least one of the upper and lower walls is provided with a plurality of spaced apart press protrusions protruding therefrom toward the other of the upper and lower walls. The stack of the connecting portion of the flexible substrate and the connecting portion of the board substrate is disposed between the upper and lower walls of the clamping frame such that the press protrusions elastically press the stack of the connecting portion of the flexible substrate and the connecting portion of the board substrate in such a manner that each of the conductive fingers of the transmission member and the corresponding one of the conductive fingers of the printed circuit board are pressed against each other by the pressing action of the press protrusions.

### BRIEF DESCRIPTION OF THE DRAWING

Other features and advantages of the present invention will become apparent in the following detailed description of the preferred embodiment of this invention, with reference to the accompanying drawings, in which:

FIG. 1 is an exploded perspective view illustrating a conventional PCB assembly on a casing;

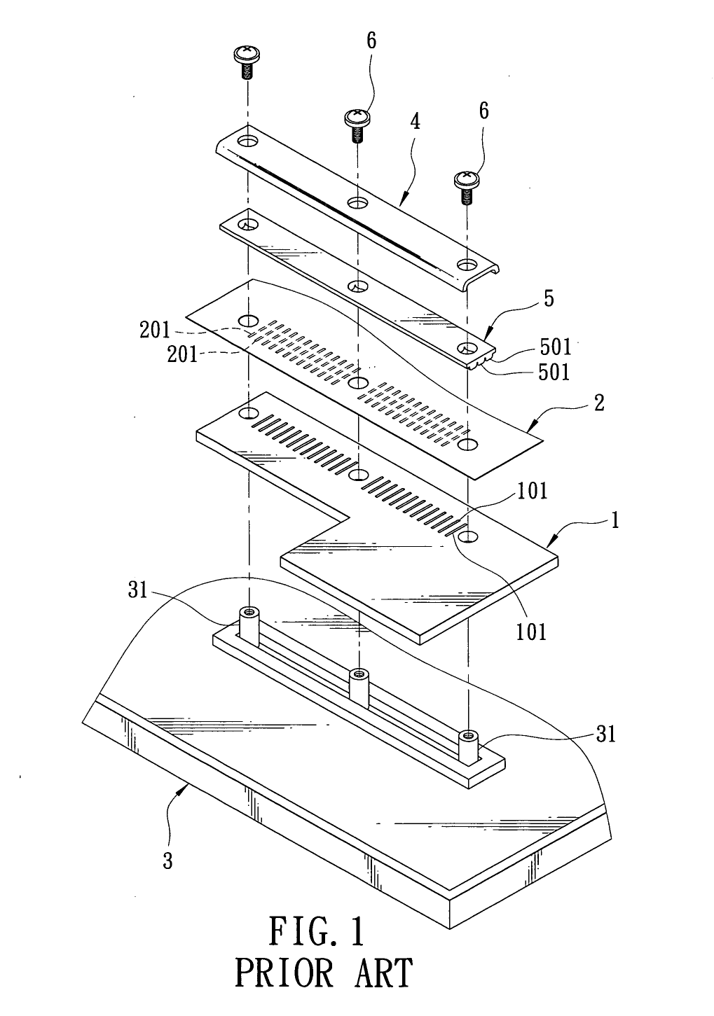

FIG. 2 is a fragmentary sectional view of the conventional PCB assembly on the case;

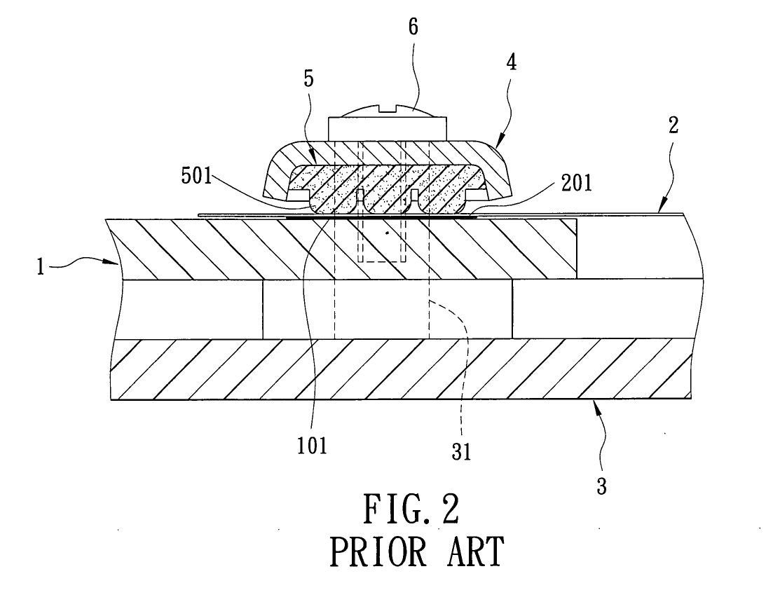

FIG. 3 is an exploded perspective view of the preferred embodiment of a circuit board assembly according to this invention;

FIG. 4 is a sectional view illustrating the configuration of an elastic clamping frame of the preferred embodiment;

FIG. 5 is a fragmentary sectional view of the preferred embodiment taken along line V-V in FIG. 3;

FIG. 6 is an assembled perspective view of the preferred embodiment;

FIG. 7 is a fragmentary sectional view of the preferred embodiment taken along line VII-VII in FIG. 6; and

FIG. 8 is a fragmentary sectional view of the preferred embodiment taken along line VIII-VIII in FIG. 7.

### DETAILED DESCRIPTION OF THE PREFERRED EMBODIMENT

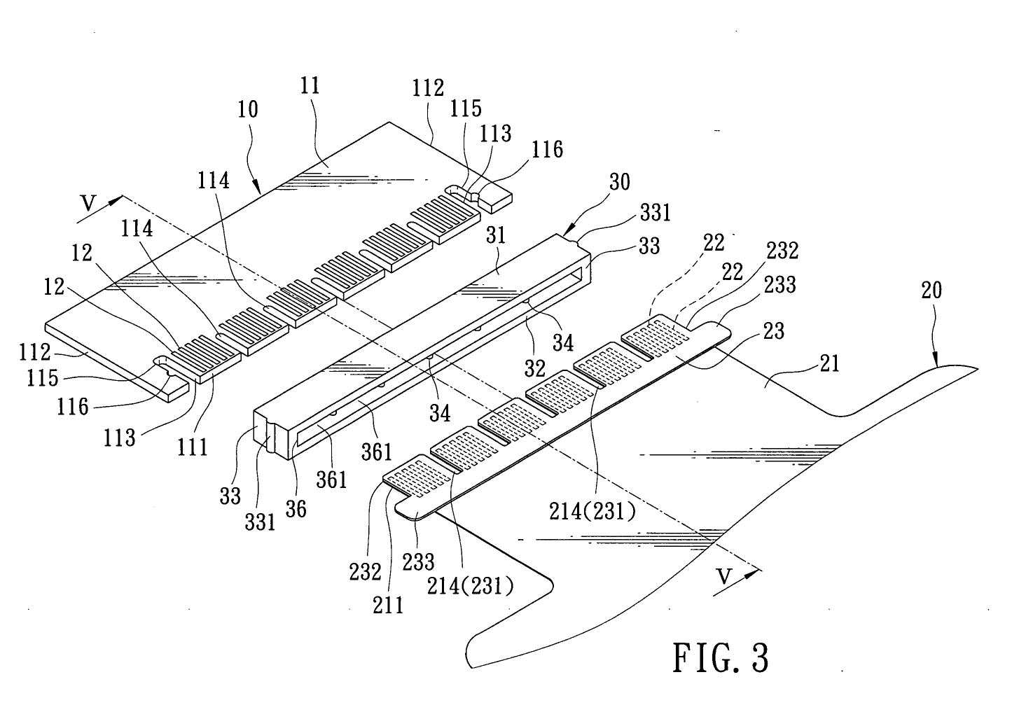

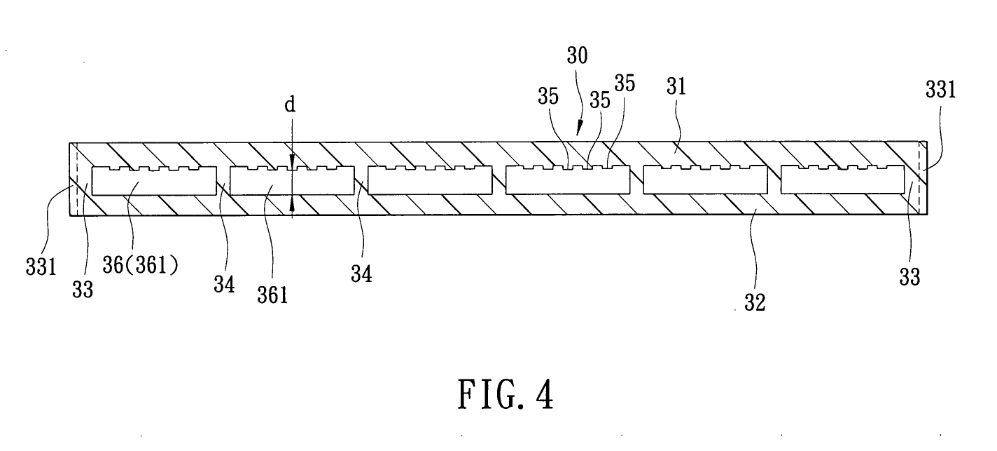

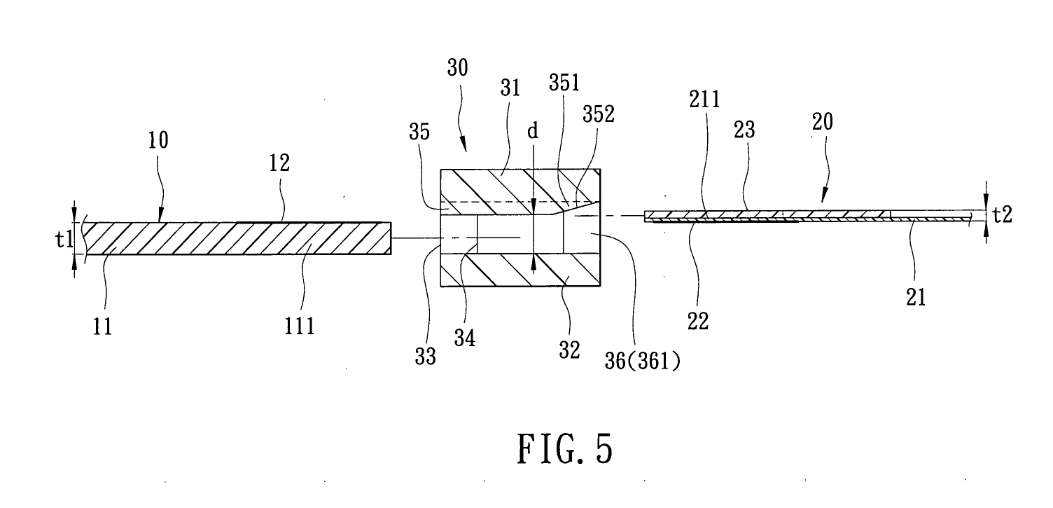

Referring to FIGS. 3 to 5, the preferred embodiment of a circuit board assembly according to this invention includes a printed circuit board (PCB) 10, a transmission member 20, and an elastic clamping frame 30.

The printed circuit board 10 includes a generally non-flexible board substrate 11 and a plurality of spaced apart conductive fingers 12. The board substrate 11 has a connecting portion 111, two opposite sides 112, and two side notches 113 formed in the connecting portion 111 and disposed adjacent to the sides 112, respectively. The connecting portion 111 has a plurality of parallel end slots 114 disposed between and parallel to the side notches 113. Each of the side notches 113 is defined by a notch-defining wall 115. The notch-defining wall 115 of each of the side notches 113 is formed with a retaining groove 116. The conductive fingers 12 are disposed on the connecting portion 113. In this embodiment, the thickness (t1) of the printed circuit board 10 is about 1.0 mm.

The transmission member 20 includes a flexible substrate 21, a plurality of spaced apart conductive fingers 22, and a reinforcing plate 23. The flexible substrate 21 has a connecting portion 211. The connecting portion 211 has a plurality of parallel end slots 214. The conductive fingers 22 are disposed on the connecting portion 211. The reinforcing plate 23 is attached to the connecting portion 211 at one side opposite to the conductive fingers 22, and has a plurality of parallel end slots 231 that are respectively aligned with the end slots 214, two opposite ends 232 opposite to each other along the length of the clamping frame 30, and two grip ears 233 protruding respectively from the ends 232. In this embodiment, the transmission member 20 is one of a flexible printed circuit (FPC) and a flexible flat cable (FFC), and the thickness (t2) of the transmission member 20 is about 0.3 mm.

The clamping frame 30 is in the form of a single piece and includes an upper wall 31, a lower wall 32, two opposite side walls 33 disposed between and interconnecting the upper and lower walls 31, 32, and a plurality of parallel partition walls 34 disposed between the side walls 33 and interconnecting the upper and lower walls 31, 32. The upper, lower, and side walls 31, 32, 33 cooperatively define a frame space 36. In this embodiment, the clamping frame 30 is made of a plastic material.

At least one of the upper and lower walls 31, 32 is provided with a plurality of spaced apart press protrusions 35 protruding therefrom toward the other of the upper and lower walls 31, 32. In this embodiment, the press protrusions 35 protrude from the upper wall 31 into the frame space 36. Each of the press protrusions 35 is in the form of an elongate bar and has a tapered end portion 351 that defines a slanted guiding surface 352 that is slanted relative to a plane defined by the upper wall 31.

Each of the side walls 33 is provided with a retaining tongue 331 protruding therefrom. The partition walls 34 divide the frame space 36 into consecutive chambers 361 distributed along the length of the clamping frame 30. Each of the chambers 361 receives some of the press protrusions 35. The distance (d) of each of the press protrusions 35 in each of the chambers 361 relative to the lower wall 32 is gradually increased from the center one toward the two endmost ones of the press protrusions 35. In this embodiment, the distances (d) of the press protrusions 35 in each of the chambers 361 relative to the lower wall 32 are 1.25 mm, 1.225 mm, 1.2 mm, 1.225 mm, and 1.25 mm, respectively.

The reinforcing plate 23, the connecting portion 211 of the flexible substrate 21, and the connecting portion 113 of the board substrate 11 are stacked one above the other to form a stack such that each of the conductive fingers 22 of the transmission member 20 is stacked on a corresponding one of the conductive fingers 12 of the printed circuit board 10. The end slots 214 in the connecting portion 211 of the flexible substrate 21 and the corresponding end slots 231 of the reinforcing plate 23 are respectively aligned with the end slots 114 in the connecting portion 113 of the board substrate 11 in a transverse direction relative to the upper and lower walls 31, 32 of the clamping frame 30. The side walls 33 of the clamping frame 30 are inserted into the side notches 113 of the board substrate 11, respectively, and engage the board substrate 11 at the side notches 113 of the board substrate 11 in a tongue-and-groove engaging manner, i.e., the retaining tongue 331 of each of the side walls 33 of the clamping frame 30 engages the retaining groove 116 in the notch-defining wall 115 of a corresponding one of the side notches 115 of the board substrate 11. Each of the partition walls 34 is inserted into a corresponding one of the end slots 114 in the connecting portion 113 of the board substrate 11, a corresponding one of the end slots 214 in the connecting portion 211 of the flexible substrate 21, and a corresponding one of the end slots 231 in the reinforcing plate 23.

It is noted that prior to assembly of the circuit board assembly, the thickness (t1) of the printed circuit board 10 plus the thickness (t2) of the transmission member 20 is greater than the distance (d) of each of the press protrusions 35 in each of the chambers 361 relative to the lower wall 32.

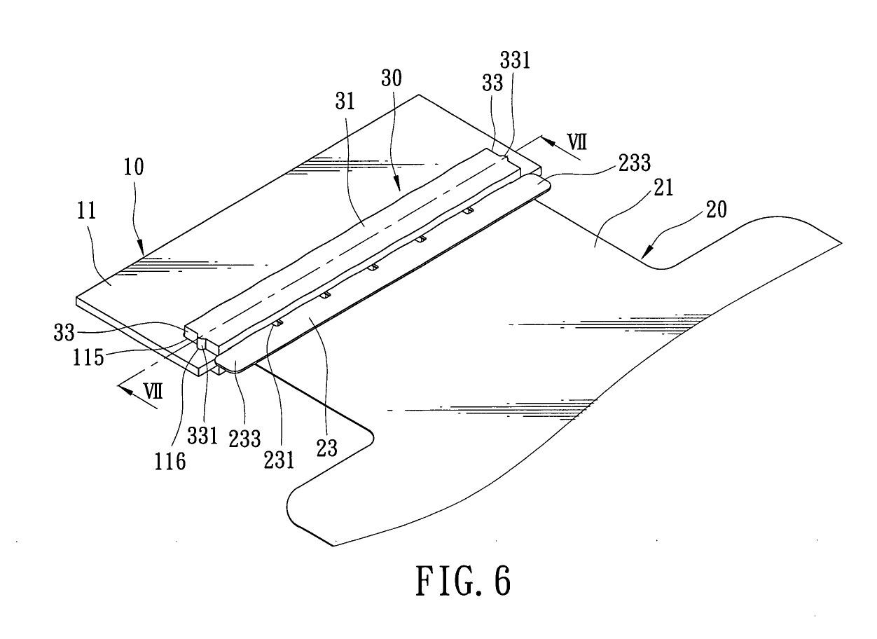

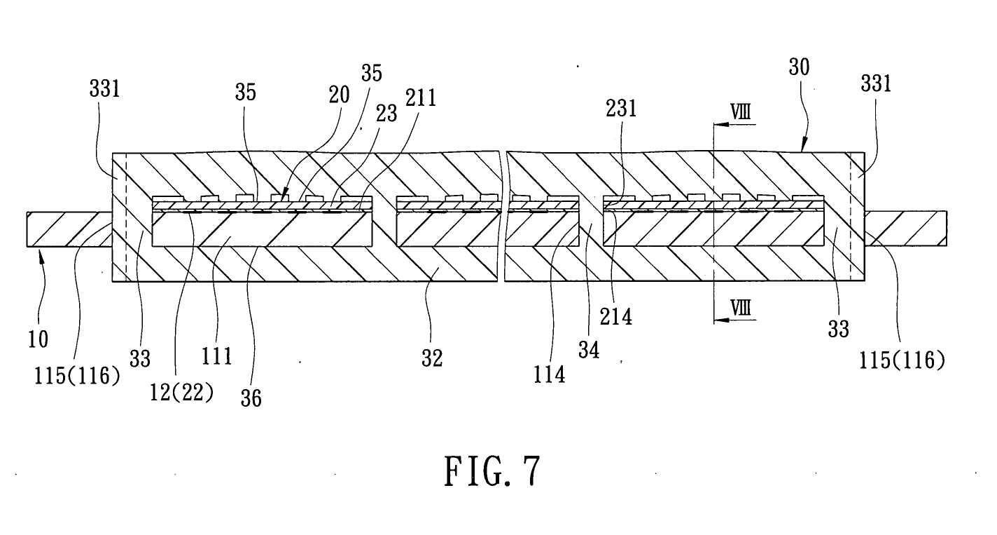

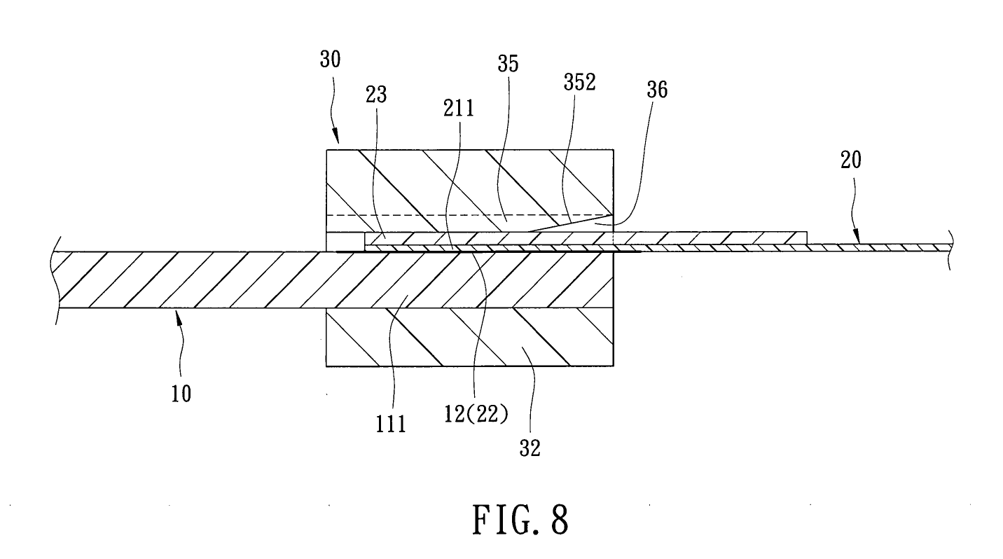

In assembly, referring to FIGS. 6 to 8, the connecting portion 111 of the board substrate 11 of the printed circuit board 10 is first inserted into the frame space 36 of the clamping frame 30. The connecting portion 211 of the flexible substrate 21 and the reinforcing plate 23 of the transmission member 20 are subsequently inserted into the frame space 36 of the clamping frame 30. The slanted guide surface 352 of each of the press protrusions 35 of the clamping frame 30 may function to guide and therefore facilitate insertion of the connecting portion 211 of the flexible substrate 21 and the reinforcing plate 23 of the transmission member 20 into the frame space 36 of the clamping frame 30. Insertion of the connecting portion 111 of the board substrate 11, the connecting portion 211 of the flexible substrate 21, and the reinforcing plate 23 of the transmission member 20 in this manner results in an elastic expansion of the clamping frame 30 in the transverse direction, and thus an increase in the distance (d) of each of the press protrusions 35 in each of the chambers 361 relative to the lower wall 32. As a consequence, the stack of the reinforcing plate 23, the connecting portion 211 of the flexible substrate 21, and the connecting portion 113 of the board substrate 11 can be tightly disposed between the upper and lower walls 31, 32 of the clamping frame 30, and the press protrusions 35 can elastically press the stack of the connecting portion 211 of the flexible substrate 21, the connecting portion 113 of the board substrate 11, and the reinforcing plate 23 such that each of the conductive fingers 22 of the transmission member 20 and the corresponding one of the conductive fingers 12 of the printed circuit board 10 can be pressed against each other by the pressing action of the press protrusions 35.

In sum, assembly of the printed circuit board 10, the transmission member 20 and the clamping frame 30 into the circuit board assembly is easy and fast. In addition, since the clamping frame 30 is in the from of a single piece and is made of a plastic material, the manufacturing costs and the weight of the circuit board assembly can be reduced.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A circuit board assembly comprising:
a printed circuit board including a board substrate and a plurality of spaced apart conductive fingers, said board substrate having a connecting portion, said conductive fingers being disposed on said connecting portion of said board substrate;
a transmission member including a flexible substrate and a plurality of spaced apart conductive fingers, said flexible substrate having a connecting portion, said conductive fingers being disposed on said connecting portion of said flexible substrate, said connecting portion of said flexible substrate and said connecting portion of said board substrate being stacked one above the other to form a stack such that each of said conductive fingers of said transmission member is stacked on a corresponding one of said conductive fingers of said printed circuit board; and
an elastic clamping frame in the form of a single piece and including upper and lower walls, at least one of said upper and lower walls being provided with a plurality of spaced apart press protrusions protruding therefrom toward the other of said upper and lower walls;
wherein said stack of said connecting portion of said flexible substrate and said connecting portion of said board substrate is disposed between said upper and lower walls of said clamping frame such that said press protrusions elastically press said stack of said connecting portion of said flexible substrate and said connecting portion of said board substrate in such a manner that each of said conductive fingers of said transmission member and the corresponding one of said conductive fingers of said printed circuit board are pressed against each other by the pressing action of said press protrusions.

2. The circuit board assembly of claim 1, wherein said clamping frame further includes two opposite side walls disposed between and interconnecting said upper and lower walls, said board substrate further having two opposite sides and two side notches formed in said connecting portion of said board substrate and disposed adjacent to said sides, respectively, said side walls of said clamping frame being inserted into said side notches, respectively.

3. The circuit board assembly of claim 2, wherein said side walls of said clamping frame engage said board substrate at said side notches of said board substrate in a tongue-and-groove engaging manner.

4. The circuit board assembly of claim 3, wherein each of said side walls of said clamping frame is provided with a retaining tongue protruding therefrom, each of said side notches of said board substrate being defined by a notch-defining wall, said notch-defining wall of each of said side notches being formed with a retaining groove, said retaining tongue of each of said side walls of said clamping frame engaging said retaining groove in said notch-defining wall of a corresponding one of said side notches.

5. The circuit board assembly of claim 2, wherein said clamping frame further includes a plurality of parallel partition walls disposed between said side walls and interconnecting said upper and lower walls, said connecting portion of said board substrate having a plurality of parallel end slots disposed between and parallel to said side notches, said connecting portion of said flexible substrate having a plurality of parallel end slots that are respectively aligned with said end slots in said connecting portion of said board substrate in a transverse direction relative to said upper and lower walls of said clamping frame, each of said partition walls being inserted into a corresponding one of said end slots in said connecting portion of said board substrate and a corresponding one of said end slots in said connecting portion of said flexible substrate.

6. The circuit board assembly of claim 5, wherein said clamping frame defines a frame space, said press protrusions of said clamping frame protruding from said upper wall into said frame space, said partition walls of said clamping frame dividing said frame space into consecutive chambers distributed along the length of said clamping frame, each of said chambers receiving some of said press protrusions, the distance of each of said press protrusions in each of said chambers relative to said lower wall being gradually increased from the center one toward the two endmost ones of said press protrusions in each of said chambers.

7. The circuit board assembly of claim 5, wherein said transmission member further includes a reinforcing plate attached to said connecting portion of said flexible substrate at one side opposite to said conductive fingers, said reinforcing plate having a plurality of parallel end slots that are respectively aligned with said end slots in said connecting portion of said flexible substrate in the transverse direction, each of said partition walls being inserted into a corresponding one of said end slots in said reinforcing plate.

8. The circuit board assembly of claim 7, wherein said reinforcing plate further has two opposite ends opposite to each other along the length of said clamping frame, and two grip ears protruding respectively from said ends of said reinforcing plate.

9. The circuit board assembly of claim 2, wherein each of said press protrusions protrudes from said upper wall, is in the form of an elongate bar, and has a tapered end portion that defines a slanted guiding surface that is slanted relative to a plane defined by said upper wall.

10. The circuit board assembly of claim 1, wherein said transmission member is one of a flexible printed circuit and a flexible flat cable.

11. The circuit board assembly of claim 1, wherein said clamping frame is made of a plastic material.
